(19) United States
(12) Patent Application Publication
(10) Pub. No.: US 2010/0109018 A1
(43) Pub. Date: May 6, 2010

(54) METHOD OF FABRICATING SEMI-INSULATING GALLIUM NITRIDE USING AN ALUMINUM GALLIUM NITRIDE BLOCKING LAYER

(75) Inventors: Zhen Chen, Goleta, CA (US); Umesh K. Mishra, Montecito, CA (US); Steven P. DenBaars, Goleta, CA (US); Shuji Nakamura, Santa Barbara, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 12/610,938

(22) Filed: Nov. 2, 2009

Related U.S. Application Data
(60) Provisional application No. 61/110,454, filed on Oct. 31, 2008.

(51) Int. Cl. H01L 29/20; H01L 29/205; H01L 21/20

(52) U.S. Cl. 257/76; 257/201; 438/478; 257/E29.091; 257/E29.089; 257/E21.09

(57) ABSTRACT

A method for fabricating a single crystal, high quality, semi-insulating (SI) gallium nitride (GaN) layer using an AlₓGa₁₋ₓN blocking layer. A buffer layer is grown on a substrate, the AlₓGa₁₋ₓN blocking layer is grown on the buffer layer, and a single crystal, high quality, SI-GaN layer is grown on the AlₓGa₁₋ₓN blocking layer. The AlₓGa₁₋ₓN blocking layer acts as a diffusion blocking layer that prevents the diffusion of donors from the substrate from reaching the SI-GaN layer. The resulting SI-GaN layer reduces parasitic current flow and parasitic capacitive effects in electronic devices.

### CROSS REFERENCE TO RELATED APPLICATION

This application claims the benefit under 35 U.S.C. Section 119(e) of co-pending and commonly-assigned U.S. Provisional Application Ser. No. 61/110,454, filed on Oct. 31, 2008, by Zhen Chen, Umesh K. Mishra, Steven DenBaars, and Shuji Nakamura, entitled “METHOD OF FABRICATING SEMI-INSULATING GALLIUM NITRIDE USING AN ALUMINUM GALLIUM NITRIDE BLOCKING LAYER,” attorney's docket number 30794.293-US-P1 (2009-256-1), which application is incorporated by reference herein.

### STATEMENT REGARDING FEDERALLY SPONSORED RESEARCH AND DEVELOPMENT

This invention was made with Government support under Grant No. N00014-05-1-0419 awarded by the Office of Naval Research Millimeterwave Initiative in Nitride Electronics (ONR MINE). The Government has certain rights in this invention.

### BACKGROUND OF THE INVENTION

1. Field of the Invention

This invention relates to gallium nitride (GaN) semiconductor electronic devices and fabrication methods, and particularly to a method for growing a high resistivity GaN layer by inserting an AlGaN layer without intentionally doping, thereby forming devices incorporating the AlGaN layer.

2. Description of the Related Art

(Note: This application references a number of different publications as indicated throughout the specification by one or more reference numbers within brackets, e.g., [x]. A list of these different publications ordered according to these reference numbers can be found below in the section entitled “References.” Each of these publications is incorporated by reference herein.)

The III-nitride based High Electron Mobility Transistor (HEMT) has shown great potential for high frequency, high power, and high temperature applications, due to its wide bandgap, high breakdown voltage, high mobility, and high electron density at the interface(s) of the AlGaN/GaN hetero structure.

The semi-insulating (SI) GaN buffer is a key prerequisite for electronics devices to decrease the parallel current between drain and source, and to ensure a good pinch-off of the channel. However, Silicon (Si) from the Silicon Carbide (SiC) substrates which is readily dissolved in the nitride could enhance the conductivity of the GaN. The usual method for growing SI-GaN is to compensate residual donors with acceptor-like states. One method is to compensate the residual donors by intentional doping. Carbon (C) has been used as an intentional dopant to achieve SI-GaN [1-3]. However, current dispersion in HEMT structures has been attributed to a carbon-related deep trap in SI-GaN:C layers [4]. Iron (Fe) has also been used to compensate for the residual donors, resulting in SI-GaN [5-6]. Other deep level transition metals and p-type dopants such as Cobalt (Co), Manganese (Mn), Chromium (Cr), Vanadium (V), Nickel (Ni), Magnesium (Mg) and Zinc (Zn) are used to compensate the donor [7-8]. All of these dopants bring traps and degrade the device's performance. In addition, the transition metals and acceptors contaminate the reactor and have a strong memory effect [9]. Moreover, there is a narrow range of doping levels that results in SI-GaN, while avoiding current dispersion caused by the impurity-related deep level(s).

FIG. 1 shows the structure of a semi-insulating GaN (SI-GaN) layer 100 on a SiC substrate 102 grown by the above described conventional methods, that is, intentionally doping. Referring to FIG. 1, a conventional SI doped GaN layer 104 (e.g., GaN:Mg, GaN:Fe, or GaN:C, i.e., GaN doped with Mg, Fe, C, respectively, etc.) is grown according to the following procedure. First, a SiC substrate 102 is subjected to cleaning at a temperature of 1100° C. or higher, and then a buffer layer (e.g. AlN 106) is formed thereon at a temperature of about 1050° C. A doped GaN layer 104 (e.g., GaN: Mg, Fe, C or GaN doped with Mg, Fe, C, etc.) is then grown on the buffer 106 as a template. In order to compensate the n-type donors in the film 104 and layer(s) 100 grown on the template film 104, dopants such as Zn, Mg, C and Fe, are doped during the growth of this conventionally highly resistive GaN layer 104. Finally, undoped GaN 100 is grown on the doped GaN template 104, wherein the undoped GaN 100 is a SI layer (SI-GaN).

FIG. 2 shows photoluminescence (PL) spectra of undoped GaN and GaN doped with Fe (GaN:Fe) films. The fact that the bandgap emission of the GaN:Fe film is much lower than that of the undoped GaN film implies that Fe-related deep levels exist in the GaN:Fe film. Such Fe-related deep levels will not only prevent recombination as a non-recombination center in optical devices, but also cause current dispersion as traps in electric/electronic devices grown on, or comprising, the GaN:Fe film.

FIG. 3 is a pulsed current-voltage (IV) curve for a HEMT grown on a GaN:Fe buffer. The radio frequency (RF) current swing is obviously compressed as compared with the direct current (DC) curve, which is referred to as current collapse/dispersion in HEMTs. The DC-RF dispersion can be attributed to the traps in the GaN channel. These results show that high-concentration Fe dopants lead to the poor performance of the devices.

The above experimental results show that the traditional method to obtain SI-GaN (doping) brings or produces traps and degrades device performance.

The second conventional method of obtaining SI-GaN is tuning growth conditions such as pressure, temperature, VIII ratio and growth rate to introduce acceptor-like defects and impurities, to compensate the background residual donors [10-13]. However, experimental results suggest that current collapse is caused by dislocation related traps [14]. Moreover, this method has poor repeatability because the dislocation density and compensating acceptors' concentrations are difficult to control accurately by adjusting growth conditions.

Referring to FIG. 4, an SI-GaN layer 400 is grown by adjusting the growth parameter(s) to induce acceptor like levels according to the following procedure. First, a SiC substrate 402 is subjected to cleaning at a temperature of 1100° C. or higher, and then a buffer layer (e.g. AlN 404) is formed thereon at a temperature around 1050° C. A first undoped GaN layer 406 is grown at low pressure on the buffer 404, as a template. A high level carbon concentration is incorporated into the first GaN layer 406 due to the low pressure growth condition(s). The undoped SI-GaN layer 400 is grown on the low pressure GaN template 406 (first undoped GaN layer). The acceptor carbon in layer 406 compensates the n-type donors in the film 400, thereby making the SI-GaN layer 400 have high resistivity.

FIG. 5 shows a Secondary Ion Mass Spectroscopy (SIMS) profile of SI-GaN grown on a SiC substrate by the second conventional method of FIG. 4, that is, introducing acceptor like levels by adjusting growth conditions. FIG. 5 shows the SIMS profile (showing Si, oxygen (O) and C profiles) of the sample structure shown in FIG. 4, wherein the line 500 represents the interface between the SI-GaN layer 400 (grown at 500 ton pressure) and low pressure GaN layer 406 (grown at low pressure, e.g., 40 torr), and the line 502 represents the interface between the low pressure GaN layer 406 and the AlN buffer layer 404. The growth pressure has no measurable effect on Si or O concentration in GaN, but has a big impact on the C concentration. The concentration of C in GaN grown at a low pressure (4×10¹⁷ atoms/cm³) is much higher than that in the GaN grown at a high pressure (2×10¹⁶ atoms/cm³). Carbon incorporation decreases as pressure increases because the increased availability of nitrogen species at a high pressure reduces the likelihood of formation of nitrogen vacancies, which are the preferred carbon sites. Carbon concentration was reported to be strongly affected by growth conditions such as pressure, temperature, ammonia flow, growth rate, and carrier gas. Carbon is also believed to be a shallow acceptor in GaN and therefore a source of donor compensation. Thus, SI-GaN can be obtained by adjusting the growth conditions to increase the C concentration. It has also been reported that increasing the dislocation density via adjusting growth conditions introduces acceptor-like states that compensate residual donors. However, experimental results suggest that current collapse is caused by carbon and/or dislocation related traps. Moreover, this method has poor repeatability because the dislocation density and compensating acceptors' concentrations are difficult to control accurately by adjusting growth conditions.

### SUMMARY OF THE INVENTION

The present invention discloses a single crystal, high quality, semi-insulating SI-GaN layer characterized by a high resistivity, e.g. a resistivity of at least 10⁵ Ω·cm and/or comprising less than 3×10¹⁵ atoms/cm³ of Silicon, for example.

The present invention further discloses a semiconductor layer structure, comprising a single crystal, high quality, semi-insulating (SI) gallium nitride (GaN) layer deposited on a substrate, wherein the substrate contains a material that diffuses into one or more layers deposited on the substrate and an intermediate layer positioned between the substrate and the SI-GaN layer blocks or prevents the material from reaching the SI-GaN layer and modifying a resistivity of the SI-GaN layer.

The substrate may be SiC, for example, and the SI-GaN layer may have a thickness ranging from 300 nm to 5 μm.

The material that diffuses into one or more layers deposited on the substrate may be a donor that reduces the resistivity of the SI-GaN layer, e.g., a Si donor concentration. The material may be a dopant, an impurity, or a donor in the one or more layers deposited on the substrate. The material may be a Si dopant and the SI-GaN layer may comprise less than 3×10¹⁵ atoms/cm³ of Si.

The intermediate layer may have a thickness and atomic structure that blocks or prevents the material from reaching the SI-GaN layer. For example, the intermediate layer may have a thickness ranging from 50 nm to 2 μm. The intermediate layer may comprise AlₓGa₁₋ₓN with 0.05<x<0.95, for example. The intermediate layer typically has a thickness and a composition (e.g., Al content) that reduces the donor's concentration in the SI-GaN layer as compared to the intermediate layer that compensates for residual donors. The intermediate layer that compensates for the residual donors is typically (1) intentionally doped with acceptors to compensate for the residual donors from the substrate, or (2) contains acceptor-like levels introduced via tuning growth conditions.

The SI-GaN layer may be used as a buffer or template layer for subsequent layers grown on the SI-GaN layer, for example, for a solid state heterojunction device comprising the SI-GaN.

The present invention further discloses a method for fabricating SI-GaN, comprising positioning an intermediate layer between a substrate and the SI-GaN layer, wherein the substrate contains a material that diffuses into one or more layers deposited on the substrate and the intermediate layer blocks or prevents the material from reaching the SI-GaN layer and modifying a resistivity of the SI-GaN layer.

### BRIEF DESCRIPTION OF THE DRAWINGS

Referring now to the drawings in which like reference numbers represent corresponding parts throughout:

FIG. 1 is a cross-sectional schematic of a structure comprising SI-GaN grown by the first conventional method: intentionally doping.

FIG. 2 shows photoluminescence (PL) spectra of undoped GaN (squares) and GaN:Fe (triangles), plotting PL intensity (arbitrary units, a.u.) vs. wavelength (nanometers, nm).

FIG. 3 shows pulsed IVs of a HEMT grown on a GaN:Fe buffer, plotting drain-source current (I_{ds}, Amps/millimeter) vs. drain-source voltage (V_{ds}, Volts) for DC (light squares), 200 nanosecond (ns) (indicated in figure), and 80 microsecond (μs) pulses (dark squares), for gate-source voltages V_{gs} ranging from 1V to −6V (from to top curves to bottom curves), wherein the loadline is 98.8 Ohms.

FIG. 4 is a cross-sectional schematic of a structure comprising SI-GaN grown by the second conventionally used method, wherein acceptor levels are introduced by adjusting growth conditions.

FIG. 5 is a SIMS profile of SI-GaN grown on a SiC substrate grown by the second conventional method, wherein acceptor levels are introduced by adjusting growth conditions and a low-pressure GaN buffer is used, and concentration of Si, C and O is plotted as a function of depth (micrometers, μm) from the surface of the SI-GaN layer (0 μm) and through the structure of FIG. 4 (increasing depth).

FIG. 6 is a cross-sectional schematic of a structure comprising SI-GaN grown by the method of the present invention.

FIG. 7 is a SIMS profile of SI-GaN grown by the method of the present invention, that is, using an AlGaN diffusion blocking layer, plotting Si, C, and O concentration as a function of depth (micrometers, μm) from the surface of the SI-GaN layer (0 μm) and through the structure comprising the SI-GaN layer on an AlGaN blocking layer on an AlN layer (increasing depth).

FIG. 8 is a cross-sectional schematic view of a HEMT grown using the GaN layer grown by the method of the present invention.

FIG. 9(a) shows a Continuous Wave (CW) power sweep at 10 GHz for a 0.65×150 μm gate HEMT on SI-GaN grown by present invention's method, plotting output power (Pₒᵤₜ, dBm) (full squares), Gain (dB) (circles), and power added efficiency PAE (%)(hollow squares) vs. input power (Pᵢₙ, dBm), wherein a high output power of 19 W/mm and a high (PAE) of 48% at 78 V drain bias implies a high device performance can be achieved by using an SI-GaN buffer grown using the present invention.

FIG. 9(b) plots power density as a function of drain bias for a HEMT of the present invention.

FIG. 10 shows CW dynamic loadline measurements, plotting drain current (A/mm) vs. drain voltage (V), at 4 GHz, of the HEMT structure on SI-GaN grown by present invention, for 30 V drain bias (squares), 40 V drain bias (circles), and 50 V drain bias (triangles), wherein good pinch-off and negligible knee walkout implies current dispersion can be avoided by using SI-GaN grown by present invention's method.

FIG. 11 is a flowchart illustrating a method of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

In view of the above, a primary object of the present invention is to provide a method for growing an SI-GaN layer by inserting an AlGaN donor diffusion blocking layer to decrease the residual donors in the GaN film. The present invention has been made in view of the above-described problems of the prior art, wherein the prior art methods compensate the donors by intentionally introducing acceptors, or acceptor-like levels. The present invention avoids the memory effect and current collapse by achieving an SI-GaN layer without doping using dopants such as C, Fe, Mg, Zn, Cr, Mo, and Co, etc. Moreover, the present invention's method avoids the current collapse problem and poor repeatability in achieving SI-GaN films, without inducing acceptor-like levels via intentionally adjusting growth conditions.

In order to accomplish the objects of the present invention, the present invention provides a method for growing an SI-GaN layer, comprising the steps of: growing a first AlN buffer layer on a SiC substrate; growing an AlₓGa₁₋ₓN diffusion blocking layer on the first buffer layer; and growing the SI-GaN layer on the AlₓGa₁₋ₓN diffusion blocking layer.

Technical Description

SI-GaN Layer

A method for growing an SI-GaN layer according to the present invention will now be described in more detail with reference to the accompanying figures.

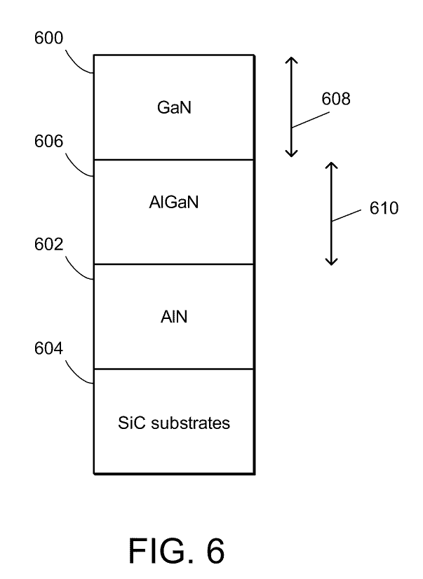

FIG. 6 is a structure for growing SI-GaN 600 according to present invention. Referring to FIG. 6, a buffer layer (e.g. AlN 602) is grown on a SiC substrate 604. It is common that a buffer layer 602 is first grown on a SiC substrate 604 to release the lattice and thermal mismatch between the substrate 604 and epilayers. The buffer layer 602 is typically grown by metal-organic chemical vapor deposition (MOCVD), or molecular beam epitaxy (MBE), for example. FIG. 6 also shows an AlGaN donor diffusion layer 606 on the buffer layer 602 and an SI-GaN layer 600 on the AlGaN layer 606.

In order to understand the mechanism for growing an SI-GaN layer 600 by the present invention, the following experiments were carried out.

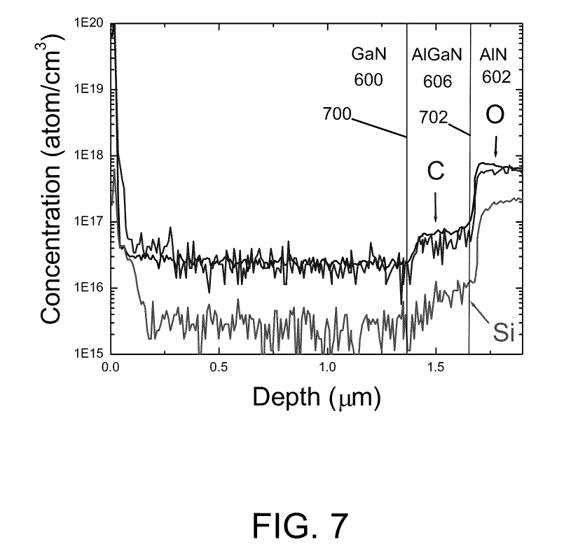

FIG. 7 shows a SIMS profile of SI-GaN 600 grown on a SiC substrate 604 using an AlGaN donor diffusion blocking buffer 606, according to present invention, wherein Si, O and C profiles in the SiC/AlN/AlGaN/GaN structure (as illustrated in FIG. 6) are shown. Si from the SiC substrate 604 which readily dissolves in the AlN buffer 602 can enhance the conductivity of the GaN 600 grown above. SIMS analysis shows that the Si concentration in the AlN buffer 602 reached a maximum of 2×10¹⁷ atoms/cm³, but decreased dramatically to 1×10¹⁶ atoms/cm³ in the AlGaN layer 606, and finally fell to 2-3×10¹⁵ atoms/cm³ in the GaN layer 600 (for Si, the detection limit is 2×10¹⁵ atoms/cm³). It is clear that the AlGaN layer 606 effectively blocked Si diffusion from SiC 604 to GaN 600. The reduced concentration of Si results in SI-GaN 600.

In FIG. 7, the line 700 represents the interface between the SI-GaN layer 600 and the intermediate layer 606, and the line 702 represents the interface between the intermediate layer 606 and the AlN buffer layer 602.

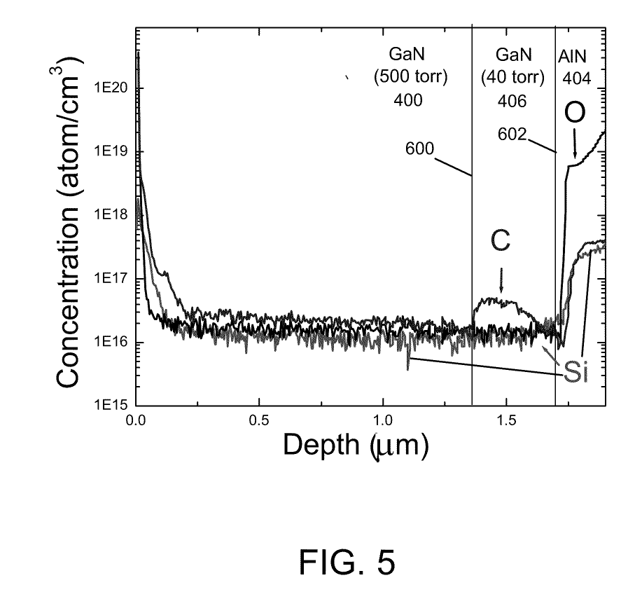

The Si concentration in GaN 600 grown by present invention (shown in FIG. 7) is around 5 times lower than that grown by conventional methods (as shown in FIG. 5). The present invention attributes the high resistivity of GaN 600 to the blocking of Si donors, from SiC substrates 604, by the AlGaN buffer layer 606 between the AlN 602 and GaN 600. In the present invention, SI-GaN 600 was achieved via reducing the residual donors by preventing the donor diffusing into the GaN film 600. Conventional methods to achieve SI-GaN compensate for residual donors by intentionally doping acceptors, or by introducing acceptor-like levels (dislocations, defects or/and impurities) via tuning growth conditions.

Thus, FIG. 6 and FIG. 7 illustrate a single crystal, high quality, SI-GaN layer 600 characterized by a high resistivity, e.g., a resistivity of at least 10⁵ Ω·cm. FIG. 6 and FIG. 7 also illustrate a semiconductor layer structure comprising a single crystal, high quality, SI-GaN layer 600, having a thickness 608, may be deposited on a substrate 604, wherein the substrate 604 (e.g., but not limited to, SiC) contains a material (e.g., Si) that diffuses into one or more layers deposited on the substrate 604 and an intermediate layer 606 positioned between the substrate 604 and the SI-GaN layer 600 blocks or prevents the material from reaching the SI-GaN layer 600 and modifying a resistivity of the SI-GaN layer 600.

For example, the intermediate layer 606 may be grown with a thickness 610, composition, and/or atomic structure that blocks or prevents the material (e.g., material that diffuses into one or more layers deposited on the substrate 604, such as donors or dopants, or atomic constituents of the substrate 604, such as Si in SiC) from reaching the SI-GaN layer 600, for example, such that the single crystal, high quality, SI-GaN layer 600 is characterized by a resistivity of at least 10⁵ Ω·cm, or such that there are less than 3×10¹⁵ atoms/cm³ of Si (e.g., Si dopant) in the SI-GaN layer 600. Thus, FIG. 6 and FIG. 7 also illustrate an example of an SI-GaN layer comprising less than 1×10¹⁶ atoms/cm³ (and typically less than 3×10¹⁵ atoms/cm³) of Si.

Device Embodiments

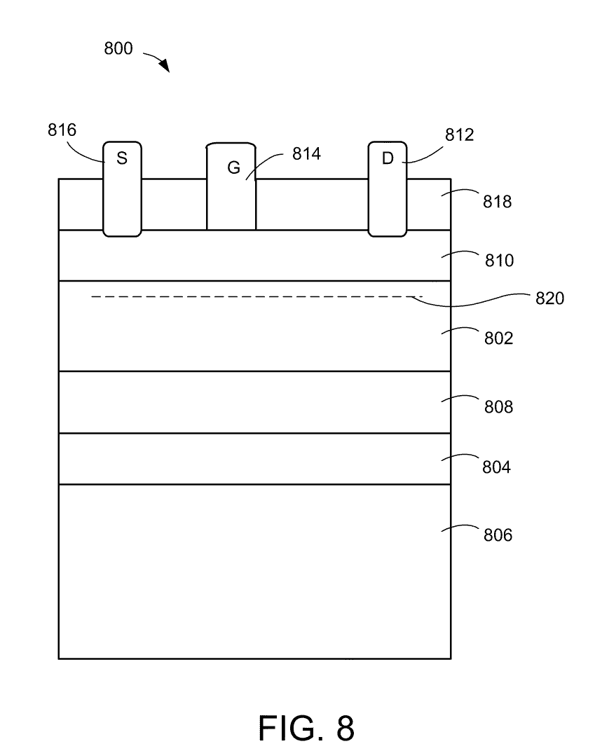

As illustrated in FIG. 8, the SI-GaN layer 600 may be a buffer or template layer for subsequent layers grown on the SI-GaN layer 600.

Heterojunctions incorporating the SI-GaN layer 600 grown by the present invention have many applications in electronic devices. A heterojunction is the interface between any two solid state materials including crystalline and amorphous structures of metallic, insulating, conducting and semiconducting materials. The present invention can be used to fabricate HEMTs which can operate at high frequencies. For example, using such technology, the present invention demonstrated devices with state-of-the-art PAE of 53.5%, and state-of-the-art associated power gain of 14.3 dB at 30 GHz. This device also demonstrated an excellent extrinsic gain cutoff frequency of 92 GHz and an extrinsic power gain cutoff frequency of 168 GHz [15-16]. While the present invention has not demonstrated a device with a higher frequency than before, the present invention has demonstrated a device with a better performance at high frequency, say 30 GHz.

Heterojunctions can confine the electron within a dopant free region where ionized impurity scattering is reduced, resulting in a two dimensional electron gas (2DEG) with very high mobility and high carrier concentration. Various heterojunction structures can also be used to fabricate metal semiconductor field effect transistors (MESFETs), metal insulator semiconductor field effect transistors (MISFETs), junction field effect transistors (JFETs) and so on. HEMTs use AlGaN/GaN to form a heterojunction, with MESFETs employing a metal/n-doped GaN layer, MISFETs utilizing a metal/insulating layer/semiconductor junction, and JFETs utilizing a p-n junction.

FIG. 8 is a cross-sectional view of a solid state heterojunction device (HEMT 800) comprising the structure of FIG. 6 e.g., a GaN layer 802 grown by the method of the present invention. The HEMT 800 shown in FIG. 8 is fabricated by growing a AlN buffer layer 804 on a SiC substrate 806, growing an AlGaN diffusion blocking layer 808 on the AlN buffer 804, growing an SI-GaN template layer 802 on the AlGaN layer 808; growing an AlGaN barrier layer 810 on the SI-GaN template layer 802, and forming a drain electrode 812, a gate electrode 814 and a source electrode 816 on the surface of AlGaN layer 810. A dielectric (insulating layer) 818 covers the surface of the AlGaN barrier layer 810 except between the AlGaN layer 810 and layers 812, 814, and 816. A triangular quantum well (two dimensional electron gas (2DEG)) 820 is formed at the interface between the SI-GaN layer 802 and the AlGaN layer 810 due to the polarization field in the GaN layer 802.

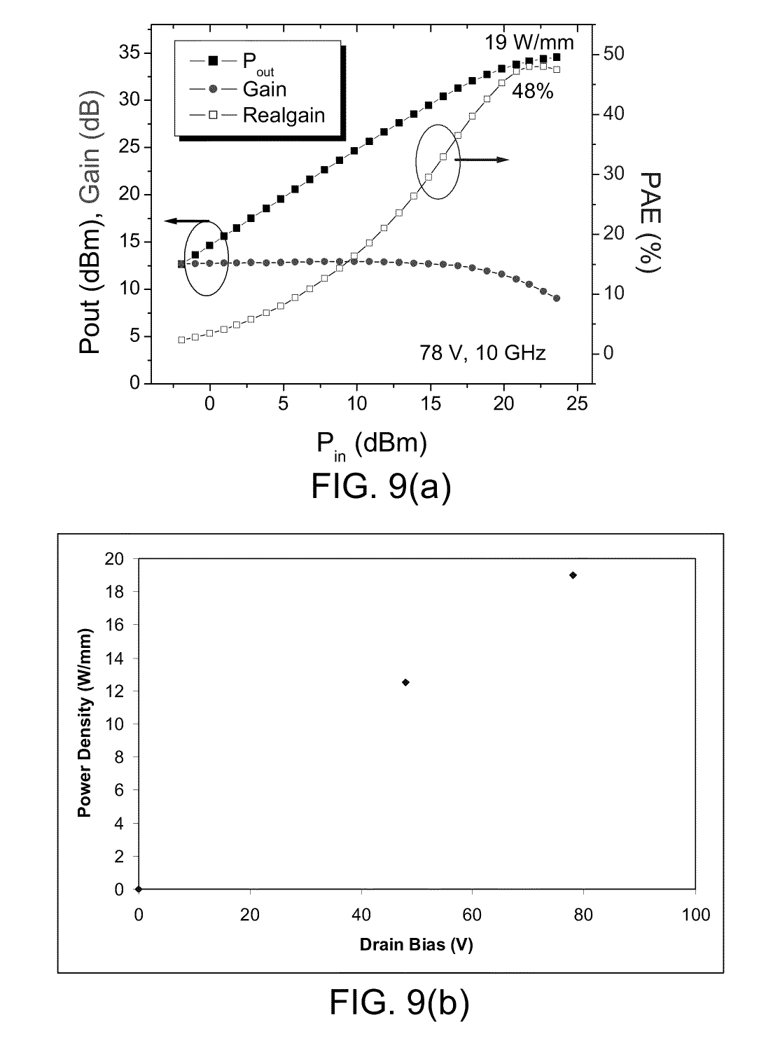

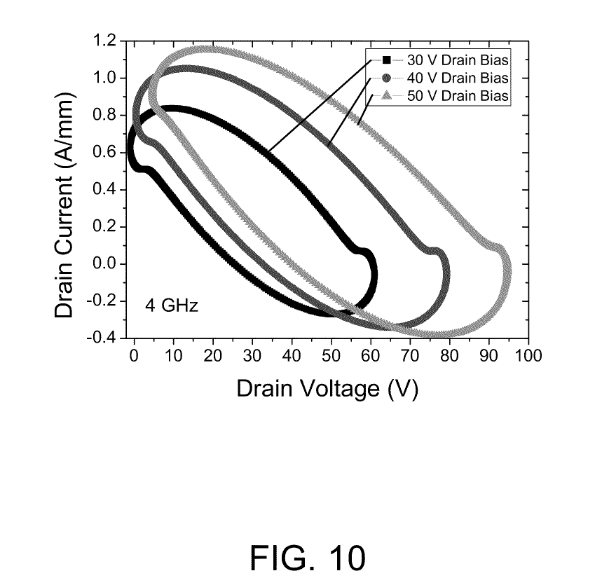

In one embodiment, the HEMT 800 structure comprises a SiC substrate 806, a buffer layer 804 that is 0.3 μm thick AlN, the SI-GaN layer that has a 1 μm thickness 608, the intermediate layer 808 that is a 0.3 μm thickness 610 of Al_{0.08}Ga_{0.92}N, a 30 nm thick Al_{0.25}Ga_{0.75}N barrier 810, an AlN layer between the barrier 810 and SI-GaN layer 802, a 120 nm thick SiNₓ passivation layer 818, a 0.65 μm gate 814 length, a Ti/Al/Ni/Au alloyed metal stack with average contact resistance of 0.3 Ω for the drain 812 and the source 816, an integrated field plate, and a 2DEG comprising a sheet carrier density and electron mobility of 8×10¹² cm⁻² and 2200 cm²/Vs, respectively (see [17]). This HEMT was characterized and the resulting data is shown in FIG. 9(a), FIG. 9(b), and FIG. 10.

FIG. 9(a) is a CW power sweep at 10 GHz for a 0.65×150 μm gate HEMT (such as that in FIG. 8) grown on SI-GaN 802 with an AlGaN insert (diffusion blocking layer such as layer 806). Such a device has excellent power density and PAE at the C and X bands, with minimal current dispersion. The power density increased linearly with increasing drain bias, which is another sign of negligible dispersion in these devices, as shown in FIG. 9(b)(FIG. 9(b) was generated using data in reference [17]).

Thus, FIG. 9(b) illustrates that the intermediate layer 808 may be grown with the thickness 610 and the composition that blocks or prevents material (material that diffuses from the substrate into one or more layers deposited on the substrate 806) from reaching the SI-GaN layer 802, such that the heterojunction structure (e.g., HEMT 800), comprising the SI-GaN 802 and layers grown on the SI-GaN layer, has negligible current dispersion. In the case of the HEMT 800 measured in FIG. 9(a) and FIG. 9(b), the negligible dispersion may be characterized by the HEMT's 800 power density increasing linearly with increasing drain bias up to the drain bias of at least 78 V and at an operating frequency of at least 10 GHz, as shown in FIG. 9(b).

FIGS. 9(a) and 9(b) also show that at a drain bias of 78 V, a power density of 19 W/mm and a PAE of 48% were achieved. Moreover, only 0.05 mA/mm of gate leakage current was observed up to 78 V drain bias in the power measurement, for the HEMT of FIGS. 9(a) and 9(b). This confirms that the SI-GaN buffer 802 has a high resistivity. Thus, the intermediate layer 808 may be grown with a thickness 610 and composition that blocks or prevents the material from reaching the SI-GaN layer 802 such that the heterojunction structure (e.g., HEMT 800) grown on and comprising the SI-GaN layer 802, and comprising a gate (e.g., 814), has a high resistivity characterized by a reduced gate leakage, for example less than 0.05 mA/mm with at least 78 V drain bias. The drain bias is between the source and the drain.

FIG. 10 shows large signal radio frequency (RF)-current-voltage (IV) measurements conducted at 4 GHz, to investigate the pinch off and current dispersion of devices such as those illustrated in FIG. 8 and measured in FIG. 9(a) and FIG. 9(b). The dynamic loadline was measured with the Maury load-pull system and a microwave transition analyzer (MTA). From the RF-IV curve shown in FIG. 10, the knee walkout is negligible up to 50 V drain bias. The present invention attributes this low dispersion to the low trap concentration of the SI-GaN channel 802.

Thus, FIG. 10 illustrates that the intermediate layer 808 may be grown with a thickness 610 and composition that blocks or prevents the material (e.g., material that diffuses from the substrate 604 into one or more layers deposited on the substrate 604, such as, but not limited to, donors or dopants) from reaching the SI-GaN layer, such that the heterojunction structure (e.g., HEMT 800), comprising a source and a drain, and grown on and comprising the SI-GaN layer 802, has negligible current dispersion. In the case of the HEMT 800, the negligible dispersion may be characterized by a negligible knee walkout up to a drain bias of 50 V.

As is apparent from the above description, according to the method of the present invention, an SI-GaN layer 600 can be grown by inserting an AlₓGa₁₋ₓN diffusion blocking layer 606, without intentionally doping or introducing acceptor levels via adjusting growth conditions. In addition, the use of the SI-GaN layer 600 grown by the present invention enables fabrication of HEMTs, MESFETs, MISFETs and JFETs having superior electrical properties because the traps in the buffer 802 and the leakage current in the GaN buffer or template layer 802 have been avoided.

Process Steps

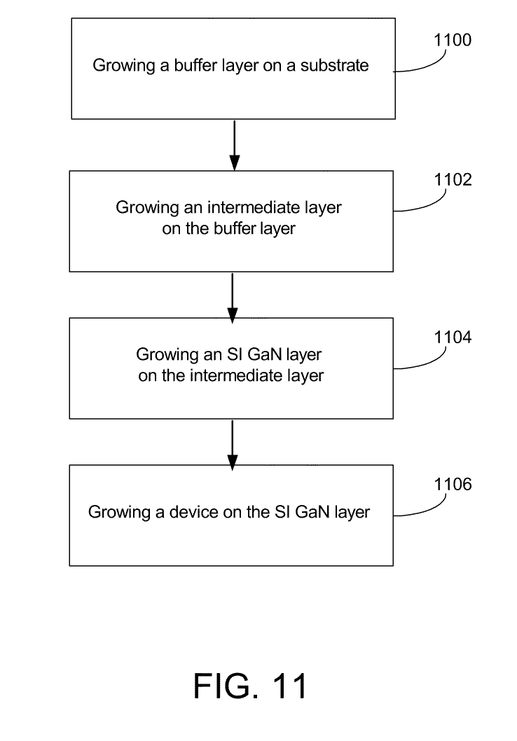

FIG. 11 illustrates a method of fabricating SI-GaN, comprising the following steps.

Block 1100 represents growing a buffer layer on a substrate (e.g., SiC), wherein the substrate contains a material that diffuses into one or more layers deposited on the substrate.

Block 1102 represents growing an intermediate layer on the buffer layer, e.g., to a thickness ranging from, but not limited to, 50 nm to 2 μm.

Block 1104 represents growing the SI-GaN layer on the intermediate layer, e.g., to a thickness ranging from, but not limited to, 300 nm to 5 μm. Thus, blocks 1100-1104 represent positioning the intermediate layer between the substrate and the SI-GaN layer, so that the intermediate layer blocks or prevents the material from reaching the SI-GaN layer and modifying a resistivity of the SI-GaN layer.

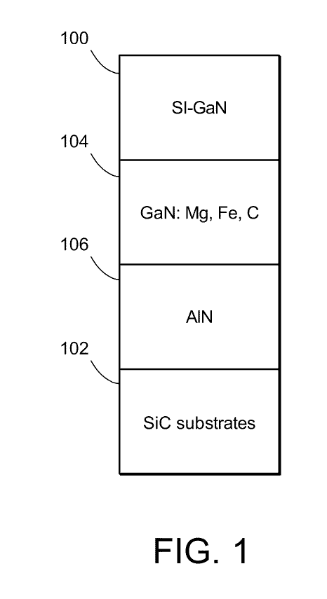

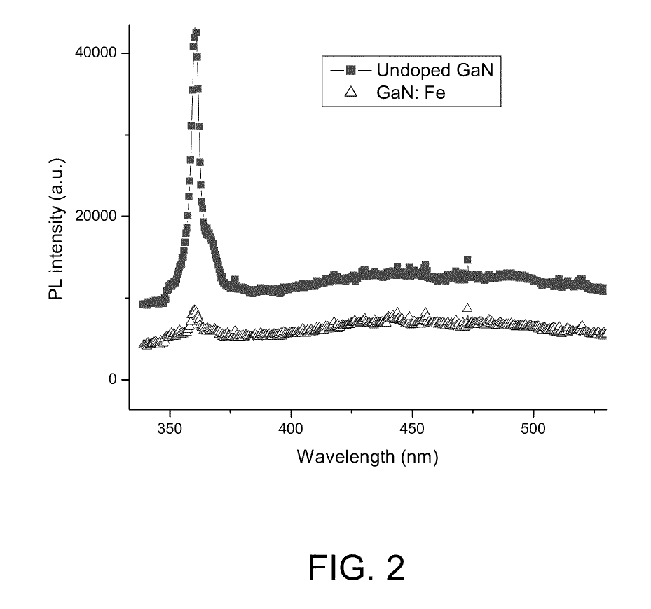

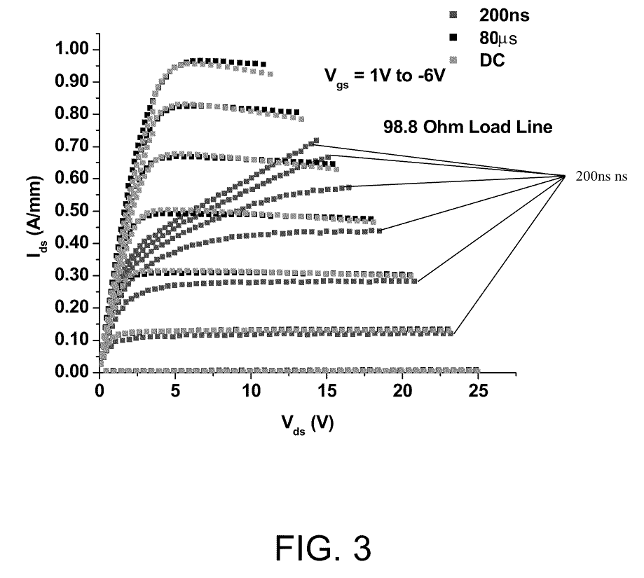

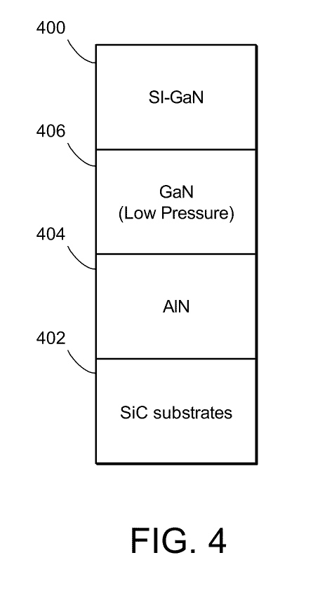

The method may further comprise selecting an atomic structure of the intermediate layer and growing the intermediate layer to a thickness that blocks or prevents the material from reaching the SI-GaN layer. The method may comprise growing the thickness and composition (e.g., Al content) of the intermediate layer that reduces the donor's or material's concentration in the SI-GaN layer as compared to the donor or material concentration in the SI-GaN layer resulting from the intermediate layer that compensates for residual donors. An intermediate layer that compensates for the residual donors (1) is typically intentionally doped with acceptors to compensate for the residual donors from the substrate (as shown in FIG. 1-3), or (2) typically contains acceptor-like levels (dislocations, defects or/and impurities), introduced via tuning growth conditions (as shown in FIGS. 4-5).

The material may be Si and the intermediate layer may be grown with a composition and to a thickness such that there are less than 1×10¹⁶ atoms/cm³ or 3×10¹⁵ atoms/cm³ of Si in the SI-GaN layer, or such that the SI-GaN layer has a resistivity of at least 10⁵ Ω·cm, for example. Thus, block 1104 also represents a single crystal, high quality, SI-GaN layer characterized by a high resistivity, e.g., a resistivity of at least 10⁵ Ω·cm, and/or comprising less than 1×10¹⁶ atoms/cm³ or 3×10¹⁵ atoms/cm³ of Si, for example. Other resistivities and concentrations are possible.

Block 1106 represents growing a device on, or comprising, the SI-GaN layer. In this way, the SI-GaN may be a buffer or template layer for subsequent layers grown on the SI-GaN layer. The subsequent device layers may be a heterojunction structure with improved performance, for example, as illustrated in FIG. 8, FIG. 9(a), FIG. 9(b) and FIG. 10.

Steps may be added or omitted.

Possible Modifications and Variations

The SI-GaN layer 600 is not limited to a particular thickness 608, but typically has a thickness 608 ranging from 300 nm to 5 μm. As noted above, the material that diffuses into one or more layers deposited on the substrate 604 is typically, but not limited to, a donor that reduces the resistivity of the SI-GaN layer 600. The material may be a dopant, an impurity, or a donor (e.g., a donor concentration such as, but not limited to, a Si concentration) in the one or more layers deposited on the substrate 604, for example.

Any substrate 604, such as but not limited to SiC, may be used. Substrates 604 such as, but not limited to, sapphire, Si, ZnO, AlN and GaN may be used, for example.

The intermediate layer 606 typically has a thickness 610 and atomic structure that blocks or prevents the material from reaching the SI-GaN layer 600. Too thin a diffusion blocking layer 606 cannot block the impurity diffusion. Too thick an electron blocking layer will block the hole flow. Therefore, the thickness 610 of the blocking layer 606 of the present invention is typically much thicker than an electron blocking layer.

For example, the intermediate layer 606 may be AlₓGa₁₋ₓN with 0<x<1, and preferably 0.05<x<0.95. The preferred thickness 610 of the intermediate layer (e.g., AlₓGa₁₋ₓN layer) ranges from 50 nm to 2 μm. However, other thicknesses 610 and compositions×are possible—the intermediate layer 606 need only have a thickness 610, composition (e.g., Al content x), and/or atomic structure that reduces the donor's or material's concentration in the SI-GaN layer 600 by blocking or preventing the material or donor concentration from reaching the SI-GaN layer 600. For example, the thickness 610 and composition (e.g., Al content) of layer 606 may reduce the donor's or material's concentration in the SI-GaN layer 600 as compared to the donor or material concentration in SI-GaN resulting from the intermediate layer that compensates for residual donors.

The thickness 610 and composition of the intermediate layer 606 is typically such that a crystalline SI-GaN layer 600 is provided.

The method was proved to be valid as applied to AlGaN materials [15-16]. In theory, it should be applicable to all the SI III-Nitrides, including AlGaN, InGaN, AlInN and AlInGaN.

### REFERENCES

The following references are incorporated by reference herein.

[1] H. Tang et al., Appl. Phys. Lett. 78 (2001) 757.

[2] J. B. Webb et al., Appl. Phys. Lett. 75 (1999) 953.

[3] D. S. Green et al., J. Appl. Phys. 95 (2004) 8456.

[4] C. Poblenz et al., J. Vac. Sci. Technol. B 23 (2005) 1562.

[5] S. Heikman et al., Appl. Phys. Lett. 81 (2002) 439.

[6] Y. Pei et al., Jpn. J. Appl. Phys. 46 (2007) L1087.

[7] U.S. Pat. No. 7,135,715, issued Nov. 14, 2006, to Saxler.

[8] U.S. Pat. No. 7,170,095, issued Jan. 30, 2007, to Vaudo.

[9] S. Heikman et al., Appl. Phys. Lett. 81 (2002) 439.

[10] U.S. Pat. No. 6,261,931, issued Jul. 17, 2001, to Keller et al.,

[11] Z. Bourgriouaa, et al., J. Cryst. Growth, 230 (2001) 573.

[12] A. E. Wickenden et al., J. Cryst. Growth 260 (2004) 54.

[13] J. Lee et al., MRS Int. J. Nitride Semicond. Res. 8 (2003) 5.

[14] P. B. Klein et al., Appl. Phys. Lett. 79 (2001) 3527.

[15] Z. Chen et al., Appl. Phys. Lett., 94 (2009) 171117.

[16] Y. Pei, IEEE Electron Dev. Lett., 30 (2009) 910.

[17] “Growth of AlGaN/GaN heterojunction field effect transistors on semi-insulating GaN facilitated by an AlGaN insert layer,” by Zhen Chen, Yi Pei, Scott Newman, David Brown, Roy Chuang, Stacia Keller, Steven. P. DenBaars, Shuji Nakamura and Umesh. K. Mishra, which publication is the Appendix of parent U.S. Provisional Application Serial No. 61/110,454, filed on Oct. 31, 2008, by Zhen Chen, Umesh K. Mishra, Steven DenBaars, and Shuji Nakamura, entitled “METHOD OF FABRICATING SEMI-INSULATING GALLIUM NITRIDE USING AN ALUMINUM GALLIUM NITRIDE BLOCKING LAYER,” attorney's docket number 30794.293-US-P1 (2009-256-1), cited in the “Cross-Reference to Related Application” above.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A semiconductor layer structure, comprising:
a single crystal, high quality, semi-insulating (SI) gallium nitride (GaN) layer deposited on a substrate, wherein the substrate contains a material that diffuses into one or more layers deposited on the substrate and an intermediate layer positioned between the substrate and the SI-GaN layer blocks or prevents the material from reaching the SI-GaN layer and modifying a resistivity of the SI-GaN layer.

2. The structure of claim 1, wherein the substrate is Silicon Carbide (SiC).

3. The structure of claim 1, wherein the SI-GaN layer has a thickness ranging from 300 nm to 5 μm.

4. The structure of claim 1, wherein the intermediate layer has a thickness and atomic structure that blocks or prevents the material from reaching the SI-GaN layer.

5. The structure of claim 4, wherein the intermediate layer is AlₓGa₁₋ₓN with 0.05<x<0.95.

6. The structure of claim 5, wherein the intermediate layer has a thickness and an Al content that reduces a donor concentration in the SI-GaN layer as compared to a donor concentration in an SI-GaN layer resulting from an intermediate layer that compensates for residual donors.

7. The structure of claim 6, wherein the intermediate layer has a thickness ranging from 50 nm to 2 μm.

8. The structure of claim 7, wherein the intermediate layer that compensates for the residual donors is:
(1) intentionally doped with acceptors to compensate for the residual donors from the substrate, or
(2) contains acceptor-like levels introduced via tuning growth conditions.

9. The structure of claim 8, wherein the donor concentration is a Silicon donor concentration.

10. The structure of claim 1, wherein the material is a donor that reduces the resistivity of the SI-GaN layer.

11. The structure of claim 1, wherein the material is a dopant, an impurity, or a donor in the one or more layers deposited on the substrate.

12. The structure of claim 1, wherein the material is a Silicon (Si) dopant and the SI-GaN layer comprises less than 3×10¹⁵ atoms/cm³ of Si.

13. The structure of claim 1, wherein the SI-GaN layer is a buffer or template layer for subsequent layers grown on the SI-GaN layer.

14. A solid state heterojunction device comprising the structure of claim 1.

15. A method of fabricating a semi-insulating (SI) GaN layer, comprising:
positioning an intermediate layer between a substrate and the SI-GaN layer, wherein the substrate contains a material that diffuses into one or more layers deposited on the substrate and the intermediate layer blocks or prevents the material from reaching the SI-GaN layer and modifying a resistivity of the SI-GaN layer.

16. The method of claim 15, wherein the substrate is SiC.

17. The method of claim 15, further comprising growing the SI-GaN layer to a thickness ranging from 300 nm to 5 μm.

18. The method of claim 15, further comprising selecting an atomic structure of the intermediate layer and growing the intermediate layer to a thickness that blocks or prevents the material from reaching the SI-GaN layer.

19. The method of claim 18, wherein the intermediate layer is AlₓGa₁₋ₓN with 0.05<x<0.95.

20. The structure of claim 19, further comprising growing the thickness and Al content of AlₓGa₁₋ₓN that reduces a donor concentration in the SI-GaN layer as compared to a donor concentration in an SI-GaN layer resulting from an intermediate layer that compensates for residual donors.

21. The method of claim 20, further comprising growing the thickness ranging from 50 nm to 2 μm.

22. The method of claim 21, wherein the intermediate layer that compensates for the residual donors is:
(1) intentionally doped with acceptors to compensate for the residual donors from the substrate, or
(2) contains acceptor-like levels, introduced via tuning growth conditions.

23. The method of claim 22, wherein the donor concentration is a silicon donor concentration.

24. The method of claim 15, wherein the material is a donor that reduces the resistivity of the SI-GaN layer.

25. The method of claim 15, wherein the material is a dopant, an impurity, or a donor in the one or more layers deposited on the substrate.

26. The method of claim 15, wherein the material is a Silicon (Si) dopant and the intermediate layer is grown with a composition and to a thickness such that there are less than 3×10¹⁵ atoms/cm³ of Si in the SI-GaN layer.

27. The method of claim 15, wherein the SI-GaN layer is a buffer or template layer for subsequent layers grown on the SI-GaN layer.

28. A single crystal, high quality, semi-insulating (SI) GaN layer characterized by a resistivity of at least 10⁵ Ω·cm.

29. The SI-GaN layer of claim 28, further comprising less than 3×10¹⁵ atoms/cm³ of Silicon in the SI-GaN layer.
